(19) United States
(12) Patent Application Publication
(10) Pub. No.: US 2022/0165762 A1
(43) Pub. Date: May 26, 2022

(54) PIXEL WITH BURIED OPTICAL ISOLATION

(71) Applicant: COMMISSARIAT A L'ENERGIE ATOMIQUE ET AUX ENERGIES ALTERNATIVES, Paris (FR)

(72) Inventors: Quentin ABADIE, Grenoble Cedex 09 (FR); François AYEL, Grenoble Cedex 09 (FR); Cédric GIROUD-GARAMPON, Grenoble Cedex 09 (FR); Yvon CAZAUX, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 17/454,627

(22) Filed: Nov. 12, 2021

(30) Foreign Application Priority Data
Nov. 20, 2020 (FR) 20 11952

(51) Int. Cl. H01L 27/146

(52) U.S. Cl. CPC H01L 27/1463; H01L 27/1464; H01L 27/14649; H01L 27/14689

(57) ABSTRACT

The invention provides an image sensor comprising a light receiving side (Fa) and, in a substrate (100), a photoelectric conversion region (PD) capable of converting light received from the light receiving side (Fa) into a charge, a storage region (SN) capable of storing a charge transferred from the photoelectric conversion region and an optical isolation element of the storage region. The optical isolation element (60) is buried in the substrate between the light receiving side and the storage region.

### TECHNICAL FIELD

The field of the invention is that of image sensors comprising, in a semiconductor substrate, a photoelectric conversion region capable of converting light received from a light receiving side of the substrate into a charge and a storage region capable of storing a charge transferred from the photoelectric conversion region. The invention is more particularly concerned with the optical isolation of the storage region in order to minimise its sensitivity to stray light and to improve the performance thereof. It finds especially application in back side illuminated (BSI) image sensors.

### PRIOR ART

Some pixel architectures for imaging include a photodiode juxtaposed with a charge storage region (or memory point) for temporarily storing information from the photodiode. This storage region is a sensitive region which especially has to be protected from light.

In a so-called global shutter sensor, that is one in which all the pixels of the sensor are exposed simultaneously, information of the pixels has to be maintained in charge or voltage memory points during the time the pixels are read. In general, this time corresponds to the reading time of the pixel matrix, if the latter is completely read. During this time, the memory point should not be disturbed by light.

In a depth sensor operating on the principle of indirect time-of-flight (iTOF), several memory points are integrated into the pixel in order to accumulate charges corresponding to two samples for the integration time. In order to accurately retrieve the depth information, both samples integrated into two capacitors should not be disturbed by light arriving directly during the integration and readout phases.

In FIG. 1 a cross-section view of a pixel formed in a P-doped silicon substrate 1 that is illuminated from its backside Fa is represented. The pixel comprises, in the substrate 1, a photoelectric conversion region PD capable of converting light received from the backside Fa into a charge and a storage region SN capable of storing a charge transferred from the photoelectric conversion region. The pixel thus comprises a device for transferring charges from the photoelectric conversion region PD to the storage region SN, for example in the form of a transfer gate GT.

The photoelectric conversion region PD comprises an N-doped well 2 and a P-doped layer 3 on the surface of the well 2. The storage region SN comprises a p-n junction consisting of a P-doped well 4 (Pwell) within which there is a highly N-doped layer acting as a readout node 5. In this exemplary embodiment, the pixel is of the voltage type and the charge storage takes place within a capacitor C_{SN} integrated into the readout circuit of the pixel.

As is noticed in FIG. 1, the p-n junction of the storage region SN is likely to receive light from the backside. The absorption of this light leads to an accumulation of stray charges in the storage zone. These stray charges correspond to an integration time later than that at which charges stored in the storage zone were integrated by the photodiode. The information stored in the storage zone is then distorted by this additional stray input, which generates noise and degrades the performance of the image sensor.

In order to minimise light arriving on a memory point, and as represented in FIG. 2, it is possible to place an optical mask MO on the light receiving side of the pixel. This optical mask MO allows the light rays entering through a microlens L in the volume of the pixel not to reach the memory point PM, at least when the mask is not too far from the memory point to be protected. As provided, for example, in documents EP 3 016 141 A1 and US 2020/0013825 A1 and schematically represented in FIG. 5, this mask MO can also be associated with an optical isolation trench TO made between the photoelectric conversion region and the storage region, this trench TO extending vertically into the substrate from the backside.

Backside masking thus proves effective when the pixel has a pitch of 3.6 μm which results in a thickness of the substrate of about 3 μm. However, the pixel pitch is increasingly smaller in global-shutter and iTOF technologies, typically less than 1.5 μm. Furthermore, for near infrared detection applications (for example at a wavelength of 950 nm), a low quantum efficiency is observed which requires the use of a thicker substrate, typically more than 6 μm thick. As represented in FIG. 3, masking becomes ineffective as light rays are then likely to reach the memory point PM. The backside opening left by the mask, close to a near-infrared wavelength, also causes strong diffraction, resulting in increased crosstalk and sensitivity to stray light. Finally, the optical isolation trench becomes difficult to integrate with such a small pixel pitch and large substrate thickness.

### DISCLOSURE OF THE INVENTION

One purpose of the invention is to minimise capture of stray light by a memory point of an image sensor, especially a sensor with small geometry pixels.

To this end, the invention provides an image sensor comprising in a substrate:
a photoelectric conversion region capable of converting light received from a light receiving side of the substrate into a charge,
a storage region capable of storing a charge transferred from the photoelectric conversion region, and
an optical isolation element of the storage region.

The optical isolation element is buried in the substrate between the light receiving side and the storage region and extends in parallel to the light receiving side.

The optical isolation element is an air cavity or is a cavity filled with an optically absorbing material in a wavelength range of interest, said cavity being arranged in the thickness of the substrate.

The cavity is typically surrounded by a semiconductor region.

Some preferred but non-limiting aspects of this image sensor are as follows:

the optical isolation element is between 350 nm and 1 μm away from a side of the substrate opposite to the light receiving side;
the optical isolation element is covered with a passivation zone;
the air cavity has a thickness such that said cavity forms a quarter-wave layer for a near infrared wavelength;
the optical isolation element is a cavity arranged in the thickness of the substrate which is filled with one or more dielectric materials;
the cavity is filled with a multilayer of dielectric materials;
the multilayer comprises two layers of SiO₂ sandwiching a layer of SiN;
the optical isolation element is a cavity arranged in the thickness of the substrate which is filled with a near infrared optically absorbing material;
the substrate has a doping gradient.

The invention is also directed to a method for manufacturing an image sensor comprising a light receiving side, comprising the following steps of:
attaching a first substrate to a bonding side of a second substrate in which a cavity is made, said transfer sealing the cavity,
forming a photoelectric conversion region capable of converting light received from the light receiving side into a charge and a storage region capable of storing a charge transferred from the photoelectric conversion region, said storage region being arranged such that the sealed cavity is interposed between the light receiving side and the storage region thereby forming an optical isolation element of the storage region.

The method comprises, between the transfer and formation steps, a step of removing the first substrate except for a sealing zone of the cavity.

Some preferred but non-limiting aspects of this image sensor are as follows:

It comprises, subsequent to the removal step and before the formation step, a step of epitaxy re-growth on the second substrate;
It comprises, before the attachment step, a step of implanting dopants into the cavity and diffusing said dopants to form a passivation zone;
It comprises forming a doping gradient between the first and the second substrate.

### BRIEF DESCRIPTION OF THE DRAWINGS

Other aspects, purposes, advantages and characteristics of the invention will become clearer from the following detailed description of preferred embodiments thereof, given by way of non-limiting example, and made with reference to the appended drawings in which:

FIG. 1 is a schematic cross-section view of a pixel of a sensor of prior art;

FIG. 2 illustrates a conventional masking of a memory point in a large geometry pixel;

FIG. 3 illustrates a conventional masking of a memory point in a small geometry pixel, for comparison with masking of FIG. 2;

FIG. 4 is a schematic cross-section view of a pixel of an image sensor in accordance with the invention;

FIG. 5 illustrates a conventional masking of a memory point in a small geometry pixel;

FIG. 6 illustrates masking of a memory point in accordance with the invention, for comparison with masking of FIG. 5;

FIG. 7 illustrates the decrease in the transmission of luminous flux towards the storage region by virtue of the buried optical isolation element provided by the invention;

FIG. 8 illustrates different steps of making an image sensor according to the invention;

FIG. 9 represents a first alternative embodiment of an image sensor according to the invention.

FIG. 10 represents a second alternative embodiment of an image sensor according to the invention;

FIG. 11 represents a third alternative embodiment of an image sensor according to the invention.

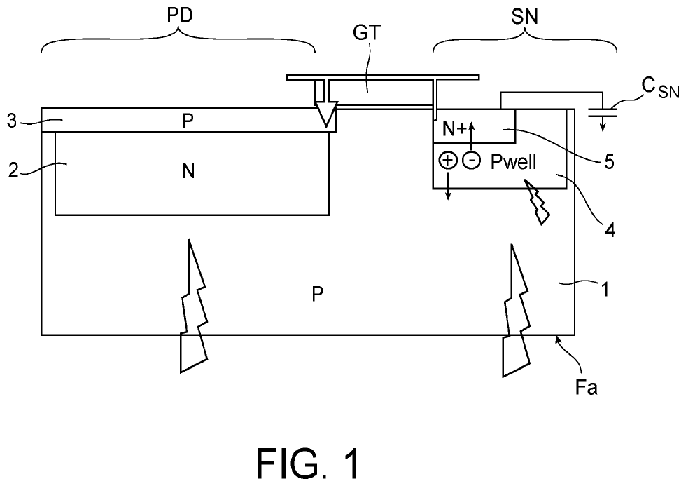

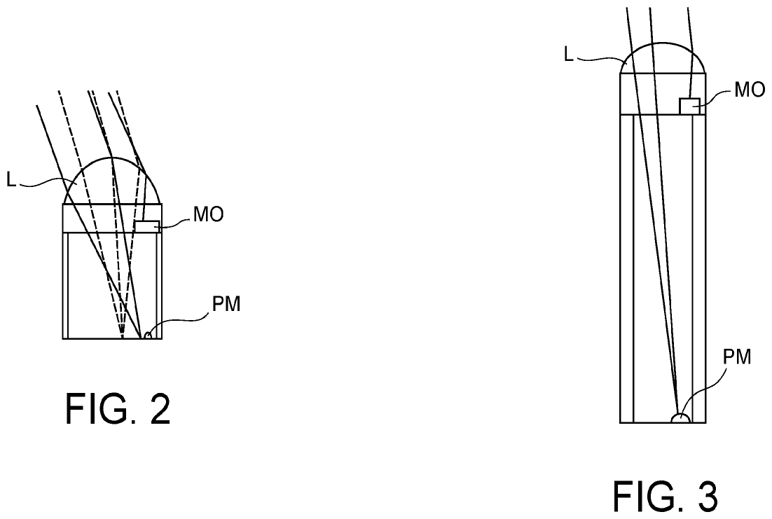

### DESCRIPTION OF THE EMBODIMENTS

The invention is concerned with an image sensor typically provided with a plurality of pixels arranged in and on a same semiconductor substrate, for example in a matrix arrangement. The image sensor comprises a light receiving side, which may be the backside of the substrate.

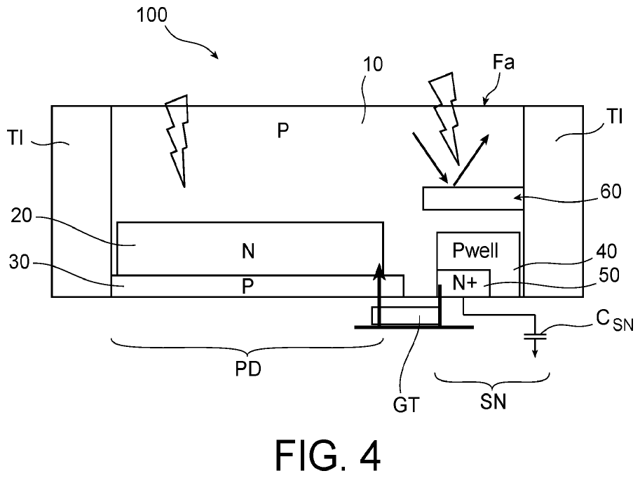

FIG. 4 represents an example of a pixel 100 of such an image sensor made in and on a P-doped silicon substrate 10 which is illuminated by its backside Fa. The pixel can be isolated from neighbouring pixels by isolation trenches TI, for example Capacitive Deep Trench Isolation (CDTI) trenches.

The pixel 100 comprises, in the substrate 10, a photoelectric conversion region PD capable of converting light received from the backside Fa of the substrate 10 into a charge and a storage region SN capable of storing a charge transferred from the photoelectric conversion region. The pixel further comprises a device for transferring charges from the photoelectric conversion region PD to the storage region, for example in the form of a transfer gate GT.

The storage region SN consists of at least one p-n junction. The pixel may be of the voltage type with charge storage taking place within a capacitor integrated into the readout circuit of the pixel, whereby charge storage and readout take place in a same region. Alternatively, as is the case in the aforementioned documents EP 3 016 141 A1 and US 2020/0013825 A1, the pixel may be of the currently-charging type with charge storage taking place within an intermediate capacitor between the photoelectric conversion region and the readout region, the storage region thus forming an intermediate region between the photoelectric conversion region and the readout region. The photoelectric conversion region PD comprises an N-doped well 20 and a P-doped layer 30 on the surface of the well 20. The storage region SN comprises a p-n junction consisting of a P-doped well 40 (Pwell) within which there is a highly N-doped layer acting as a readout node 50. In this exemplary embodiment, the pixel is of the voltage type and charge storage takes place within a capacitor C_{SN} integrated into the readout circuitry of the pixel.

The pixel 100 according to the invention further comprises in the substrate an optical isolation element 60 of the storage region SN which extends in parallel to the backside. This optical isolation element 60 is more particularly buried in the substrate 10 between the light receiving side Fa and the storage region SN.

It thus blocks and prevents light from reaching the storage region and generating stray charges therein. It typically takes the form of a horizontal barrier parallel to the backside Fa and which is arranged under the storage region SN in a direction from the front side to the backside.

This barrier may be at least 3 μm, preferably at least 5 μm, away from the backside Fa. Considering a substrate thickness 10 of 6 μm, the barrier is preferably at least 5.5 μm away from the backside Fa.

The storage region SN typically has a thickness in the range of 200 to 300 nm. In order that the barrier does not impact the doped zones forming the storage region, the latter is preferably 350 nm to 1 μm away from the front side of the substrate opposite to the backside Fa, for example 400 nm. Furthermore, the barrier preferably completely covers the storage region, taking alignment effects into account, with an overshoot of 100 nm remaining acceptable.

It should be noted here that the pixel may include several junctions in connection with a plurality of storage regions which need to be protected from stray light. The footprint of the buried optical isolation element may be adapted accordingly to provide this protection. Alternatively, the pixel may comprise a plurality of buried optical isolation elements.

The buried optical isolation element 30 typically takes the form of a cavity formed in the thickness of the substrate 1 and which is left open to air or filled with one or more materials. The cavity is here surrounded by a semiconductor region, typically a silicon region. The silicon used is not necessarily limited to a particular crystal orientation.

In one possible embodiment, the cavity is not filled with one or more metals. The optical isolation of the storage zone achieved by means of this element may act in light reflection and/or absorption.

In one exemplary embodiment, the optical isolation element 60 is thus an air cavity arranged in the thickness of the substrate 10. In another exemplary embodiment, the optical isolation element 30 is a cavity arranged in the thickness of the substrate which is filled with one or more dielectric materials (oxide, nitride). The cavity may for example be filled with a multilayer of dielectric materials, such as a multilayer comprising a layer of SiN sandwiched by two layers of SiO₂.

The thickness of the air cavity or the thickness of the layer(s) of material filling the cavity may be optimised to maximise light reflection at a given wavelength, typically at a near-infrared wavelength, for example at 940 nm. The air cavity may thus have a thickness such that said cavity forms a quarter-wave layer for a near infrared wavelength, for example a thickness of 235 nm to maximise reflection at 940 nm. For the same purpose, a dielectric layer in the cavity may also form a quarter-wave layer, for example with a thickness of 120 nm for a layer of SiO₂ or a thickness of 170 nm for a layer of SiN to maximise reflection at 940 nm.

In another exemplary embodiment, the optical isolation element is a cavity arranged in the thickness of the substrate which is filled with an optically absorbing material in a wavelength range of interest, for example in the near infrared. The optically absorbing material is, for example, germanium.

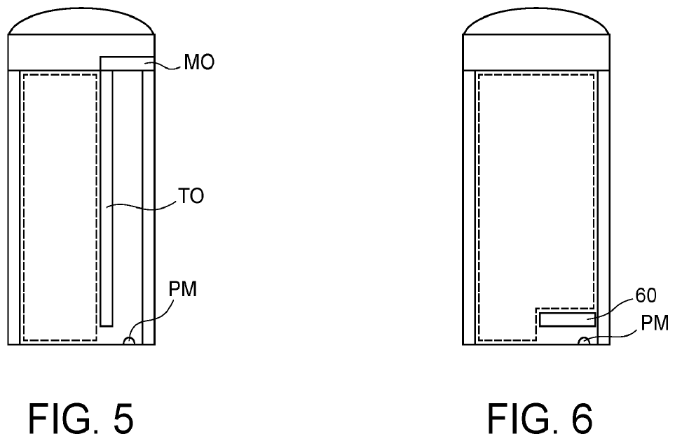

Apart from dispensing with the backside mask MO and the lateral optical isolation trench TO, while ensuring effective masking even for the smallest pixels, the optical isolation provided by the invention also has the advantage of increasing the useful absorption volume in the photoelectric conversion region PD. A conventional masking of a memory point PM by means of the backside mask MO and the lateral optical isolation trench TO is thus represented in FIG. 5. By way of comparison, masking of a memory point in accordance with the invention with the buried optical isolation element 60 is represented in FIG. 6. It is noticed that the volume useful for capturing photons, delimited by dotted lines in these FIGS. 5 and 6, is greater with the invention. This results in an increase in the signal-to-noise ratio, which is particularly useful for applications in the near infrared (850-940 nm) where the quantum efficiency of imagers is low. The optical isolation advocated by the invention is also advantageous for positioning the microlens (centred) and further comes with by a larger opening at the pixel inlet which results in a reduction of diffraction and crosstalk.

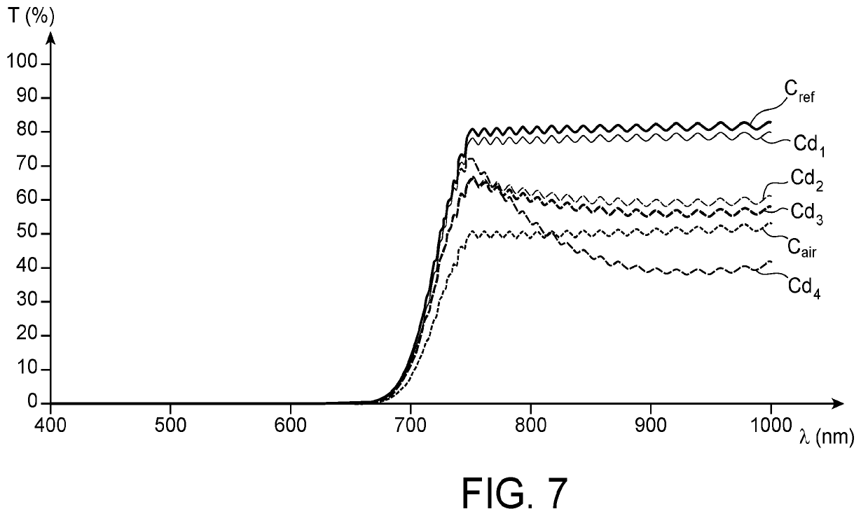

1D optical simulations have been carried out to verify the interest of the buried optical element of the invention in a pixel with a thickness of 6 μm of Si and an optical element buried under 5.5 μm of Si. The transmission rate T of light to the storage region as a function of wavelength λ (in nm) has been represented in FIG. 7. In this figure:
curve C_{ref} represents the transmission rate in the absence of the optical isolation element of the invention (i.e. through 6 μm of Si);
curve Cₐᵢᵣ represents the transmission rate through a 235 nm thick air cavity;
curve Cd₁ represents the transmission rate through a cavity filled with 120 nm thick SiO₂;
curve Cd₂ represents the transmission rate through a cavity filled with a multilayer SiO₂ (170 nm thick)/SiN (120 nm thick);
curve Cd₃ represents the transmission rate through a cavity filled with a multilayer SiO₂ (170 nm thick)/SiN (120 nm thick)/SiO₂ (170 nm thick);
curve Cd₄ represents the transmission rate through a cavity filled with a multilayer SiO₂ (170 nm thick)/SiN (120 nm thick)/SiO₂ (170 nm thick)/SiN (120 nm thick).

These simulations show absorption in silicon in the visible range (typically for a wavelength below 700 nm) that is sufficiently high that the light does not reach the optical isolation element. They also show a high transmission in silicon in the near infrared range (curve C_{ref}), while the optical isolation element according to the invention allows, in the near infrared range, for a reduction in the luminous flux reaching the storage region by 40 to 60%. These simulations show that oxide filling is not very efficient (curve Cd₁) and that it is preferable to create an empty cavity (air) or filled with a multilayer.

The following describes different alternatives of a method for manufacturing an image sensor according to the invention.

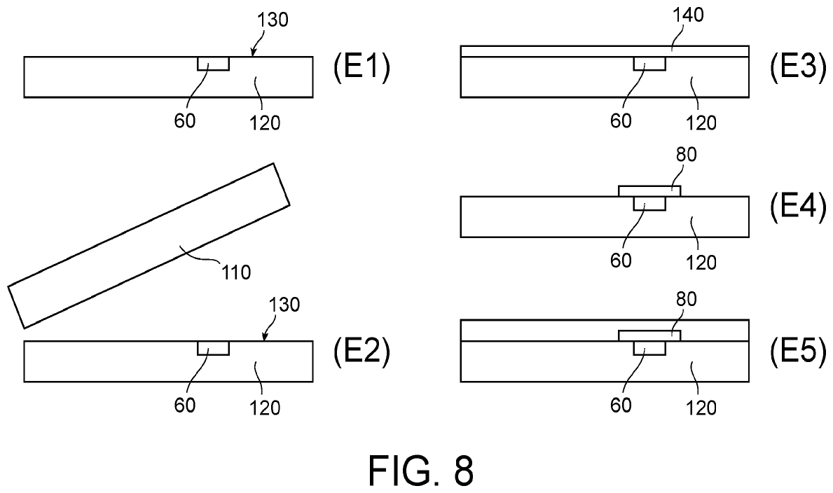

With reference to FIG. 8, this method starts with a step of providing a first substrate 110 and a second substrate 120, for example silicon substrates. With reference to FIG. 8, this method continues with a step (E1) of forming, for example by photolithography, a cavity 60 on a so-called bonding side 130 of the second substrate and, if necessary, filling this cavity.

The method then comprises a step (E2) of attaching the first substrate 110 onto the bonding side 130 of the second substrate 120 in which the cavity is made, said attachment sealing the cavity. This attachment can be carried out by molecular silicon-to-silicon bonding, without any precise positioning restriction. This attachment may be preceded by a step of implanting dopants in the cavity and diffusing said dopants to form a passivation zone 70 represented in FIG. 7 which, by passivating the edges of the cavity, makes it possible to minimise the dark current.

The first substrate is then thinned in a step (E3) to keep only a thin layer 140 with a thickness of typically less than 2 μm.

In a first alternative embodiment, the method continues directly with the CMOS method for forming the pixels of the image sensor. This method thus comprises forming a photoelectric conversion region capable of converting light received from a light receiving side into a charge and a storage region capable of storing a charge transferred from the photoelectric conversion region. The storage region is arranged such that the sealed cavity 60 is interposed between a light receiving side (in this case the backside of the second substrate, opposite to the bonding side) and the storage region, the sealed cavity thus forming an optical isolation element of the storage region.

Within the scope of this first alternative, a number of imperfections are likely to occur at the bonding interface between the first substrate thinned and the second substrate, such as a slight bending of the strips at the silicon that could interfere with the collection of carriers by the photodiode.

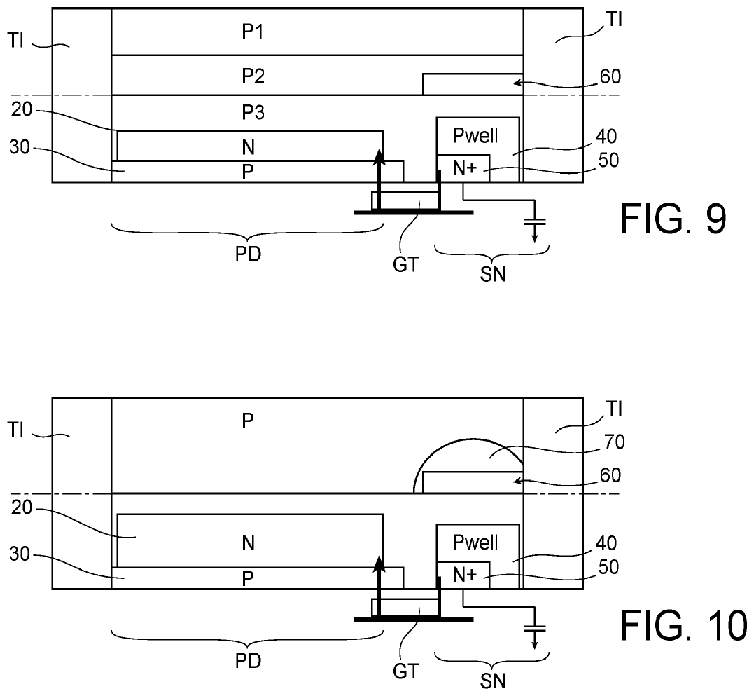

As represented in FIG. 9, one way to address this potential problem to some extent is to vary doping of the silicon substrates to create a potential gradient favourable to collection of carriers. A doping gradient can thus be achieved on either side of the bonding interface by providing a doping level P3 of the first transferred substrate that is lower than the doping level P2 of the second substrate in which the cavity is made. It is also possible to achieve a doping gradient in the second substrate with a doping level P1 on the backside such that P1<P2<P3. It will be noted that the creation of this doping gradient perpendicular to a plane intercepting the optical isolation element is not exclusive to the first alternative but can also be achieved within the scope of the alternatives described below.

In a second and a third alternative, following the thinning step (E3), the method continues with a step (E4) of removing, for example by photolithography, the thin layer 140 resulting from the thinning of the first substrate except for a sealing zone 80 of the cavity 60. The bonding interface between the first and second substrates is thus eliminated, thereby being not negatively impacted by imperfections thereof.

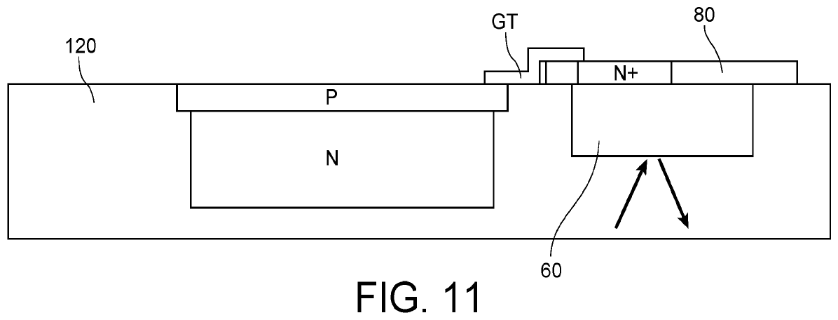

In the second alternative, the method directly continues after step (E4) with the CMOS method for forming the pixels of the image sensor. As represented in FIG. 11, in this case the transfer gate GT from the photoelectric conversion region to the storage region straddles the second substrate 120 and the sealing zone 80 of the cavity 60 attached to the second substrate.

In this second alternative, part of the bonding interface remains under the gate. It is possible to create a stronger electric field to facilitate passage of charges to the storage region by locally adjusting the potentials and doping.

In the third alternative, the method continues after step (E4) with a step (E5) allowing the substrate to be laid flat, this step comprising epitaxially regrowing and eliminating an excess thickness present at the sealing zone. This step (E5) continues with the CMOS method for forming the pixels of the image sensor. In this case the transfer gate can be planar.

The invention extends to pixels using 3D stacking technologies where detection is performed on a first substrate and reading is performed on a second substrate. In such a case, the memory point can be partly positioned on the second substrate, especially in order to minimise the size of the memory point to be protected from light on the first substrate while having a storage capacity which value can be adjusted on the second substrate. The part of the memory point located on the second substrate can be conventionally masked, for example by a metal screen. The part of the memory location remaining on the first substrate consists of the p-n junction which can be protected from light by the buried optical isolation element provided by the invention.

1. An image sensor comprising, in a substrate (100), a photoelectric conversion region (PD) capable of converting light received from a light receiving side (Fa) of the substrate into a charge, a storage region (SN) capable of storing a charge transferred from the photoelectric conversion region and an optical isolation element of the storage region,
characterised in that the optical isolation element (60) is buried in the substrate between the light receiving side (Fa) and the storage region (SN) and extends in parallel to the light receiving side, the optical isolation element being an air cavity or being a cavity filled with an optically absorbing material in a wavelength range of interest, said cavity being arranged in the thickness of the substrate.

2. The image sensor according to claim 1, wherein the optical isolation element (60) is 350 nm to 1 μm away from a side of the substrate opposite to the light receiving side.

3. The image sensor according to claim 1, wherein the optical isolation element (60) is covered with a passivation zone (70).

4. The image sensor according to claim 1, wherein the air cavity has a thickness such that said cavity forms a quarter-wave layer for a near infrared wavelength.

5. The image sensor according to claim 1, wherein the optical isolation element is a cavity arranged in the thickness of the substrate which is filled with a near infrared optically absorbing material.

6. The image sensor according to claim 1, wherein the substrate has a doping gradient.

7. A method for manufacturing an image sensor comprising a light receiving side (Fa), comprising the following steps of:
attaching (E2) a first substrate (110) to a bonding side (130) of a second substrate (120) in which a cavity (60) is made, said attachment sealing the cavity,
forming a photoelectric conversion region (PD) capable of converting light received from the light receiving side into a charge and a storage region (SN) capable of storing a charge transferred from the photoelectric conversion region, said storage region being arranged such that the sealed cavity is interposed between the light receiving side and the storage region thereby forming an optical isolation element of the storage region.

8. The method according to claim 7, comprising, between the attachment and formation steps, a step of removing (E4) the first substrate except for a sealing zone (80) of the cavity.

9. The method according to claim 8, comprising, following the removal step (E4) and before the formation step, a step (E5) of epitaxy re-growth on the second substrate.

10. The method according to claim 9, comprising, before the attachment step, a step of implanting dopants into the cavity and diffusing said dopants to form a passivation zone (70).

11. The method according to claim 10, comprising forming a doping gradient between the first and second substrates.
